(19) United States
(12) Patent Application Publication
(10) Pub. No.: US 2026/0295678 A1
(43) Pub. Date: Oct. 1, 2026

(54) FORMING A SINGLE CRYSTAL STRUCTURE DURING ADDITIVE MANUFACTURING

(71) Applicant: Beehive Industries, LLC, Centennial, CO (US)

(72) Inventor: Richard J. Grylls, Lima, OH (US)

(21) Appl. No.: 19/489,775

(22) PCT Filed: Jun. 7, 2024
(86) PCT No.: PCT/US2024/033078

§ 371 Date: Dec. 3, 2025

Related U.S. Application Data
(60) Provisional application No. 63/507,051, filed on Jun. 8, 2023.

(51) Int. Cl. B22F 10/50; B22F 10/28; B22F 12/41; B22F 12/60; B33Y 10/00; B33Y 30/00; B33Y 40/00

(52) U.S. Cl. CPC B22F 10/50; B22F 10/28; B22F 12/41; B22F 12/60; B33Y 10/00; B33Y 30/00; B33Y 40/00; B22F 2998/10

(57) ABSTRACT

A layer of metal powder is spread on a powder bed and sintered. A portion of the layer is melted in a shape of a cross-section of an additively manufactured 3D printed part. Sintered powder adjacent to a melted edge of the shape is removed. The portion of the layer is remelted. Spreading, sintering, melting, removing, and remelting is repeated at each successive layer. In another aspect, a layer of metal powder is spread on a powder bed. A portion of the layer is melted in the shape of the cross-section of the part. Spreading and melting of L−1 successive layers of powder corresponding to L−1 respective layers of the part is repeated. Following the spreading and melting of a topmost layer, a tool removes a polycrystalline shell adjacent to each respective layer's melted edge to a depth of L layers relative to a present layer.

### CROSS-REFERENCE TO RELATED APPLICATION

This application for patent claims the benefit of and priority to U.S. Provisional Patent Application Ser. No. 63/507,051 entitled “Forming a Single Crystal Structure During Additive Manufacturing” filed in the United States Patent and Trademark Office on Jun. 8, 2023, the entire content of which is incorporated herein by reference as if fully set forth below in its entirety and for all applicable purposes.

### TECHNICAL FIELD

Aspects described herein are generally related to additive manufacturing and more particularly, to forming a single crystal structure during additive manufacturing.

### BACKGROUND

Additive manufacturing of single crystals (sometimes called mono-crystal) using powder bed technologies such as laser powder bed fusion (L-PBF) and electron beam melting (EBM) may yield parts having a single crystal (SX) region bordered by a polycrystalline (PX) region. The polycrystalline region is undesirable. In some examples, the polycrystalline region effectively forms a shell around the single crystal region. In some examples, the shell may have a thickness of about 1 to 2 mm. In some examples, the powder bed around a periphery of the single crystal region may act as a nucleation site for the polycrystalline region.

Engineers and scientists may be addressing issues related to polycrystalline growth; however, effective methods of avoiding the polycrystalline shell, converting the polycrystalline shell to a single crystal, or removing the polycrystalline shell (in situ) during additive manufacturing remain elusive.

### BRIEF SUMMARY

The following summary is provided to facilitate an understanding of some of the innovative features unique to the examples disclosed and is not intended to be a full description. A full appreciation of the various aspects of the examples can be gained by taking the entire specification, claims, drawings, and abstract as a whole.

In one example, a method of additively manufacturing a three-dimensional (3D) printed part is disclosed. In the example, the method includes spreading a layer of unmelted metal powder on a powder bed, melting a portion of the layer in a shape of a cross-section of a corresponding layer of a plurality of layers of the additively manufactured 3D printed part, removing, utilizing a tool, metal powder adjacent to a first melted edge of the shape, remelting at least one of: the first melted edge, or the portion of the layer in the shape of the cross-section of the corresponding layer of the plurality of layers of the additively manufactured 3D printed part, and repeating the spreading, the melting, the removing, and the remelting at each successive layer of the plurality of layers of the additively manufactured 3D printed part.

In one example, an apparatus is described. In the example, the apparatus may include a powder bed, a recoater head configured to recoat the powder bed with unmelted metal powder, a tool actuator coupled to the recoater head, and a tool coupled to the tool actuator. In the example, the apparatus is configured to spread, utilizing the recoater head, the layer of unmelted metal powder on the powder bed, melt a portion of the layer in a shape of a cross-section of a corresponding layer of a plurality of layers of the additively manufactured 3D printed part, remove, utilizing the tool, metal powder adjacent to a first melted edge of the shape, remelt at least one of: the first melted edge, or the portion of the layer in the shape of the cross-section of the corresponding layer of the plurality of layers of the additively manufactured 3D printed part, and repeat the spread, the melt, the remove, and the remelt at each successive layer of the plurality of layers of the additively manufactured 3D printed part.

In one example, a system is described. In the example, the system includes one or more processors, one or more memories coupled to the one or more processors, a powder bed, at least one of: a laser or an electron beam gun focused on the powder bed and coupled to the one or more processors, a recoater head coupled to the one or more processors, a tool actuator coupled to the recoater head and the one or more processors, and a tool coupled to the tool actuator. In the example the one or more processors are configured to, individually or collectively, based at least in part on information stored in the one or more memories, spread, utilizing the recoater head, the layer of unmelted metal powder on the powder bed, melt a portion of the layer in a shape of a cross-section of a corresponding layer of a plurality of layers of the additively manufactured 3D printed part, remove, utilizing the tool, metal powder adjacent to a first melted edge of the shape, remelt at least one of: the first melted edge, or the portion of the layer in the shape of the cross-section of the corresponding layer of the plurality of layers of the additively manufactured 3D printed part, and repeat the spread, the melt, the remove, and the remelt at each successive layer of the plurality of layers of the additively manufactured 3D printed part.

In one example, a method of additively manufacturing a three-dimensional (3D) printed part is described. In the example, the method includes spreading a layer of unmelted metal powder on a powder bed, melting a portion of the layer in a shape of a cross-section of a corresponding layer of a plurality of layers of the additively manufactured 3D printed part, the portion of the layer having a melted edge, repeating the spreading and the melting of L−1 successive layers of metal powder corresponding to L−1 respective layers of the plurality of layers of the additively manufactured 3D printed part, where L is an integer greater than 1. The method further includes removing, following the spreading and melting of a topmost layer, utilizing a first tool, a polycrystalline shell adjacent to the melted edge of each respective layer to a depth of L layers relative to the topmost layer.

In one example, an apparatus is described. In the example, the apparatus includes a powder bed, a recoater head configured to recoat the powder bed with an unmelted metal powder, a tool actuator coupled to the recoater head, and a tool coupled to the tool actuator. In the example, the apparatus is configured to spread, utilizing the recoater head, a layer of unmelted metal powder on the powder bed, melt a portion of the layer in a shape of a cross-section of a corresponding layer of a plurality of layers of the additively manufactured 3D printed part, the portion of the layer having a melted edge, repeat the spreading and the melting of L−1 successive layers of metal powder corresponding to L−1 respective layers of the plurality of layers of the additively manufactured 3D printed part, where L is an integer greater than 1. The apparatus is further configured to remove, following the spreading and the melting of a topmost layer, utilizing the first tool, a polycrystalline shell adjacent to the melted edge of each respective layer to a depth of L layers relative to the topmost layer.

In one example, a system is described. In the example, the system includes one or more processors, one or more memories coupled to the one or more processors, a powder bed, at least one of: a laser or an electron beam gun focused on the powder bed and coupled to the one or more processors, a recoater head coupled to the one or more processors, a tool actuator coupled to the recoater head and the one or more processors, and a tool coupled to the tool actuator. In the example, the one or more processors are configured to, individually or collectively, based at least in part on information stored in the one or more memories, spread, utilizing the recoater head, a layer of unmelted metal powder on the powder bed, melt a portion of the layer in a shape of a cross-section of a corresponding layer of a plurality of layers of the additively manufactured 3D printed part, the portion of the layer having a melted edge, repeat the spreading and the melting of L−1 successive layers of metal powder corresponding to L−1 respective layers of the plurality of layers of the additively manufactured 3D printed part, where L is an integer greater than 1. The apparatus is further configured to remove, following the spreading and the melting of a topmost layer, utilizing the first tool, a polycrystalline shell adjacent to the melted edge of each respective layer to a depth of L layers relative to the topmost layer.

These and other aspects will become more fully understood upon a review of the detailed description which follows. Other aspects, features, and examples will become apparent to persons having ordinary skill in the art upon reviewing the following description of specific examples in conjunction with the accompanying figures. While features may be discussed relative to particular examples and figures below, all examples can include one or more of the features discussed herein. In other words, while one or more examples may be discussed as having certain advantageous features, one or more of such features may also be used in accordance with the other examples discussed herein. Similarly, while examples may be discussed below in terms of a specific apparatus, device, system, or method, it should be understood that such examples can be implemented in various other apparatus, devices, systems, and methods.

### BRIEF DESCRIPTION OF THE DRAWINGS

The accompanying figures, in which like reference numerals refer to identical or functionally similar elements throughout the separate views and which are incorporated in and form a part of the specification, further illustrate the examples and, together with the detailed description, serve to explain the aspects disclosed herein.

FIG. 1 is a photomicrograph of a sample of a single crystal nickel-based superalloy, such as but not limited to Alloy 5, exhibiting a polycrystalline shell according to some aspects of the disclosure.

FIG. 2 is an illustration of a pair of three-dimensional printed metal products formed using an electron beam melting process according to some aspects of the disclosure.

FIG. 3 is a simplified, not-to-scale, artist's rendition of a plurality of the uppermost layers of a cross-section of a sample of a metal product undergoing fabrication utilizing an electron beam melting metal additive manufacturing process according to some aspects of the disclosure.

FIG. 4 is an illustration of a second sample of a metal product fabricated using a laser powder bed fusion metal additive manufacturing process according to some aspects of the disclosure.

FIG. 5 is a pictographic example of a series of images that, taken together, may be used to explain the fabrication of a metal product using a powder bed fusion metal additive manufacturing process according to some aspects of the disclosure.

FIG. 6 is a pictographic example of a series of images that, taken together, may be used to explain the fabrication of a metal product using a powder bed fusion metal additive manufacturing process according to some aspects of the disclosure.

FIG. 7 is a block diagram of an example of a system that may be used to remove unmelted metal powder from the edges of one or more additively manufactured printed layers of a 3D printed metal part during fabrication according to some aspects of the disclosure.

FIG. 8 is a flow chart illustrating an example process of metal 3D printing utilizing additive manufacturing and an electron beam melting process in accordance with some aspects of the disclosure.

FIG. 9 is a flow chart illustrating an example process of metal 3D printing utilizing an additive manufacturing process, such as a laser powder bed fusion process or an electron beam melting process, in accordance with some aspects of the disclosure.

### DETAILED DESCRIPTION

The particular values and configurations discussed in the following non-limiting examples can be varied and are cited merely to illustrate one or more examples and are not intended to limit the scope thereof.

Examples will now be described more fully hereinafter with reference to the accompanying drawings. The examples disclosed herein can be modified within the scope of this disclosure and should not be construed as limiting; instead, these examples are provided so that this disclosure will be thorough and complete and fully convey the scope of the disclosure to persons having ordinary skill in the art. Like numbers refer to like elements throughout.

The detailed description set forth below in connection with the appended drawings is intended as a description of various configurations and is not intended to represent the only configurations in which the concepts described herein may be practiced. The detailed description includes specific details to provide a thorough understanding of various concepts. However, it will be apparent to persons having ordinary skill in the art that these concepts may be practiced without these specific details. In some examples, well-known structures and components are shown in block diagram form in order to avoid obscuring such concepts.

The terminology used herein is for the purpose of describing particular examples only and is not intended to be limiting. As used herein, the singular forms “a,” “an,” and “the” are intended to include the plural forms as well, unless the context clearly indicates otherwise. It will be further understood that the terms “comprise” and/or “comprising,” when used in this specification, specify the presence of stated features, values, steps, operations, elements, components, and/or groups thereof but do not preclude the presence or addition of one or more other features, values, steps, operations, elements, components, and/or groups thereof.

Throughout the specification and claims, terms may have nuanced meanings suggested or implied in context beyond an explicitly stated meaning. Likewise, the phrase “in one example,” as used herein, does not necessarily refer to the same example and the phrase “in another example” as used herein does not necessarily refer to a different example. It is intended that the scope of the disclosure may encompass the subject matter of one or more examples in whole or in part.

Unless otherwise defined, all terms (including technical and scientific terms) used herein have the same meaning as commonly understood by one of ordinary skill in the art. It will be further understood that terms, such as terms defined in commonly used dictionaries, should be interpreted as having a meaning that is consistent with their meaning in the context of the relevant art and will not be interpreted in an idealized or overly formal sense unless expressly so defined herein.

It will be understood that particular examples described herein are shown by way of illustration and not limitation. Aspects described herein can be employed in various examples without departing from the scope of the disclosure. Those persons having ordinary skill in the art will recognize or be able to ascertain that numerous equivalents to the specific aspects and procedures described herein may exist. Such equivalents are considered to be within the scope of this disclosure and are covered by the claims.

The word “a” or “an,” when used in conjunction with the term “comprising” may mean “one.” Still, the use of the word “a” or “an” when used in conjunction with the term “comprising” may also be consistent with the meaning of “one or more,” “at least one,” and “one or more than one.” The term “or” may be used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if the order is inferred or described in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. Persons having ordinary skill in the art will understand that typically there is no limit on the number of items or terms in any combination, unless otherwise apparent from the context.

All aspects disclosed and claimed herein may be made and executed without undue experimentation in light of the present disclosure. While the aspects have been described in terms of preferred examples, it will be apparent to persons having ordinary skill in the art that variations may be applied to the aspects described herein without departing from the concept, spirit, and scope of the disclosure and claims. All similar variations, substitutes, and modifications apparent to those persons having ordinary skill in the art are deemed to be within the spirit, scope, and concept of the disclosure as defined by the appended claims.

In metal additive manufacturing, a desired (e.g., finished, final, completed) metal part may be mathematically represented by thousands of horizontal cross-section “slices” stacked one atop another (e.g., one above another, one over another). A three-dimensional (3D) printer may be configured to direct either a laser beam or an electron beam at a leveled bed of unmelted metal powder and, using the energy realized at the focal point of the laser beam or electron beam, melt a shape corresponding to a cross-sectional layer of the desired metal part into a topmost layer of the unmelted metal powder. After melting the shape into the layer, a next layer of unmelted metal powder is added atop the just processed layer. A respective shape corresponding to the cross-sectional slice of the layer of the metal part is melted into the next layer. The process of adding the next layers of unmelted metal powder and causing the laser beam or electron beam to melt the next shapes corresponding to respective slices of the metal product into the next layers is repeated until the desired 3D metal part is produced.

Several categories of metal additive manufacturing processes exist today. One category may be referred to as powder bed fusion or powder bed melting. In this category are two subcategories. A first subcategory may be referred to as selective laser melting or laser powder bed fusion (L-PBF). In L-PBF, a high-power laser beam is used to selectively melt a metal powder into a shape corresponding to a cross-section of one of thousands of slices of a desired (e.g., finished, final, completed) metal part. The high-power laser beam selectively joins or welds the particles of the metal powder together. Once all layers have been printed, the metal part may be removed from the unmelted metal powder. Many parts made using the L-PBF process require heat treatment to strengthen the metal end-product.

A second subcategory may be referred to as electron beam melting (EBM). The electron beam melting process does not use a high-power laser. Instead, as the name implies, it uses a high-power electron beam to selectively melt the metal powder. Unlike a laser process, which may be carried out at room temperature and pressure and with normal air or within an envelope of an inert gas, an electron beam melting process must be carried out in a vacuum, in a vacuum chamber that may be maintained at extremely hot temperatures (e.g., 1,000-1,500 degrees Celsius).

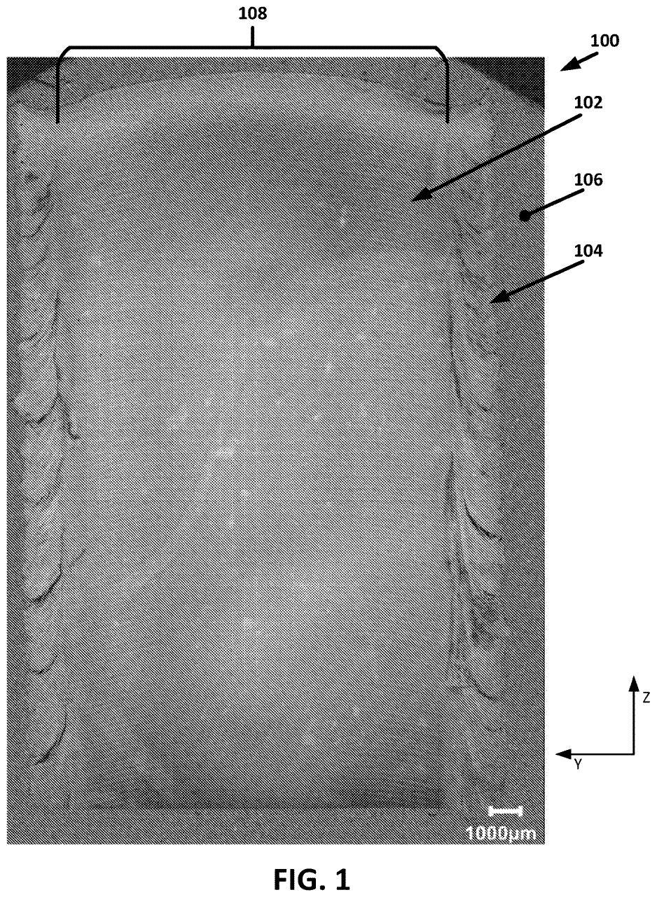

FIG. 1 is a photomicrograph of a first sample 100 of a single crystal 102 nickel-based superalloy, such as but not limited to Alloy 5 (hereinafter “SX superalloy”) exhibiting a polycrystalline shell 104 according to some aspects of the disclosure. As used herein, the terms single crystal (as used perhaps in engineering parlance) and single grain (as used perhaps in metallurgical parlance) are synonymous. The first sample 100 was produced using an additive manufacturing process during which a plurality of SX superalloy unmelted metal powder layers had melted therein a corresponding plurality of cross-sections (e.g., shapes) of a respective plurality of layers of a desired metal product. During the additive manufacturing process, each cross-sectional shape of the desired metal product was melted, one atop the next, using an electron beam melting process. After each slice was melted (e.g., printed), a new layer of unmelted metal powder was added atop a just solidified layer. Then, the new respective cross-sectional slice was melted into the new layer of unmelted metal powder and into at least a portion of the previously solidified layer. The finished metal product is formed of a continuous intermixed plurality of solidified cross-sectional slices.

However, the continuous intermixed plurality of solidified cross-sectional slices does include discontinuities manifested as a polycrystalline shell 104. It is noted that the entire central region 108 is a single crystal despite the appearance of some random discolorations (i.e., whitish drops, splotches, and linear streaks visible in the first sample 100). The random discolorations in the central region 108 of the first sample 100 are attributed to the handling of the first sample 100.

The polycrystalline shell 104 appears in a zone between the solidified single crystal 102 SX superalloy (in the central region 108) and a region of unmelted metal powder (not shown) outboard of the polycrystalline shell 104. The first sample 100 was obtained using cross-section microscopy. According to cross-sectional microscopy processes, the first sample 100 may be embedded in an epoxy 106, cross-sectioned, and polished in a Y-Z plane (the X-axis pointing into the plane of the paper, perpendicular to the Y-Z plane). The first sample 100 was then etched using an etching solution. The etching permits visualization of various grains in the first sample 100.

The first sample 100 illustrates the microstructure of the single crystal 102 SX superalloy (with polycrystalline shell 104) produced by an electron beam melting process according to some aspects of the disclosure. The first sample 100 includes a plurality of horizontal layers in the X-Y plane (not distinguishable in the illustration). Each layer is formed atop a preceding layer using the described additive manufacturing process that forms the layers in the positive Z-axis direction from the bottom of the first sample 100 (e.g., at the origin of the Z-axis) toward the top of the first sample 100.

The edge grains of the polycrystalline shell 104 may form by nucleation from metal powder attached to a surface of the desired finished metal product (i.e., attached to an outer boundary of metal powder intentionally melted using the electron beam). According to aspects described herein, removing the metal powder from the surface of the desired finished product may prevent nucleation of the edge grains.

As known to those persons of ordinary skill in the art, the term grain may be used to refer to crystallites of varying, randomly distributed, small sizes that together make up a piece of solid metal. Grain boundaries define surface areas where various grains contact each other. Grain boundaries are generally a weakness in the material (i.e., a weakness in the piece of solid metal). The grain boundaries, where two grains meet, have a disordered structure that reduces the strength of the metal in comparison to a sample of the solid metal where the grains have an ordered structure (i.e., a single crystal). Accordingly, removing grain boundaries could be advantageous, at least in terms of producing metals of superior strength (superior in comparison to samples that have pluralities of grain boundaries).

Some methods of casting metal products allow the cast metal to grow as one single grain. Such methods may be generally referred to as investment castings or lost wax castings. In an investment casting process, accurate castings may be formed within a mold formed around a wax (or similar material) copy of the ultimately desired finished metal product. The wax is removed by melting and is replaced with molten metal poured into the mold. Investment castings, with single-grain metal finished products, may be used for high-performance metal applications, such as the first stage of turbine blades of a jet engine, where the first stage blades are positioned behind a combustor that is expelling very hot gas (that is above the melting point of the metal used to fabricate the turbine blades) and are spinning around a shaft of the jet engine at high speed with large loads. However, because the chemistry of the investment cast metal has been optimized and the investment cast products have no grain boundaries, the metal parts can withstand high temperatures and loads.

At least one challenge with investment casting is that engineers are limited in the shapes that can be made. For example, complex shapes may be designed to be good for aerodynamic, cooling, and performance aspects. Yet, those shapes may be impractical or impossible to fabricate using an investment casting process (e.g., because the internal copy of the desired part within an investment cast mold, when melted, loses important details of the desired part). Additionally, the creation of investment cast molds is a time-consuming process. Although more than one finished product may be cast in a given investment cast mold, once the investment cast mold is filled with molten metal to create the one or more than one finished product, the investment cast mold will need to be destroyed to extricate the one or more than one finished product from the mold.

Accordingly, significant benefits may be realized by producing a metal part using an additive manufacturing process (distinct from the investment casting process) where the additively manufactured metal part is a single crystal metal with one grain throughout the metal part. Furthermore, an additive manufacturing process lends itself to the formation of complex shapes, the inclusion of cooling channels, speed and ease of modeling and prototyping, speed and ease of modification of the shape for prototyping, and repeatability with accuracies dependent on the 3D printer that formed a finished metal part, rather than on accuracies dependent on each iteration or copy of an investment cast mold. Moreover, very few companies in the world are able to make high quality, high precision, single crystal metal parts using the investment casting process. The small number of companies, coupled with a high demand for high quality, high precision, single crystal metal parts, results in lead times that could exceed one or more years.

As indicated by the scale included in FIG. 1, the thickness of the polycrystalline shell 104 is about 1 mm (1000 μm). Certain parts, such as, but not limited to high performance turbine blades, may have a desired exterior wall thickness of 1 mm. Given that the thickness of a desired single crystal exterior wall and an undesired polycrystalline shell undesirably coupled to that exterior wall are on the same order, chemical etching may not be a feasible way to remove the polycrystalline shell. For example, due to different localized concentrations of the chemical etch solution, bubble formation (as a byproduct of an etching process), surface contaminants, and surface features of a given part, in any given unit of time, a chemical etch may remove 1 mm of material from one area and, immediately adjacent to the one area, remove 2 mm of material. Such a difference in the depth of material removed by a chemical etching process could conceivably remove both the desired single crystal exterior wall and the undesired polycrystalline shell.

According to some aspects, the thickness of the polycrystalline shell 104 is independent of the thickness of the single crystal metal beneath the polycrystalline shell 104. Using FIG. 1 as an example, without limitation, the thickness in the Y-axis dimension of the single crystal 102 (i.e., the metal in the central region 108) is about 10 mm. In comparison, the thickness in the Y-axis dimension of each of the left and right portions of the polycrystalline shell 104 is about 1 mm. It has been observed that the thickness of the polycrystalline shell 104 remains at about 1 mm regardless of whether the thickness of the single crystal 102 in the central region 108 is increased (e.g., to 100 mm) or decreased (e.g., to 3 mm).

In practice, without at least partial elimination of nucleation material (e.g., unmelted metal powder adjacent to solidified metal powder) from the desired external wall surface, the growth of the polycrystalline shell 104 makes it difficult, if not impossible, to manufacture single crystal metal walls that have a thickness of about 1 mm.

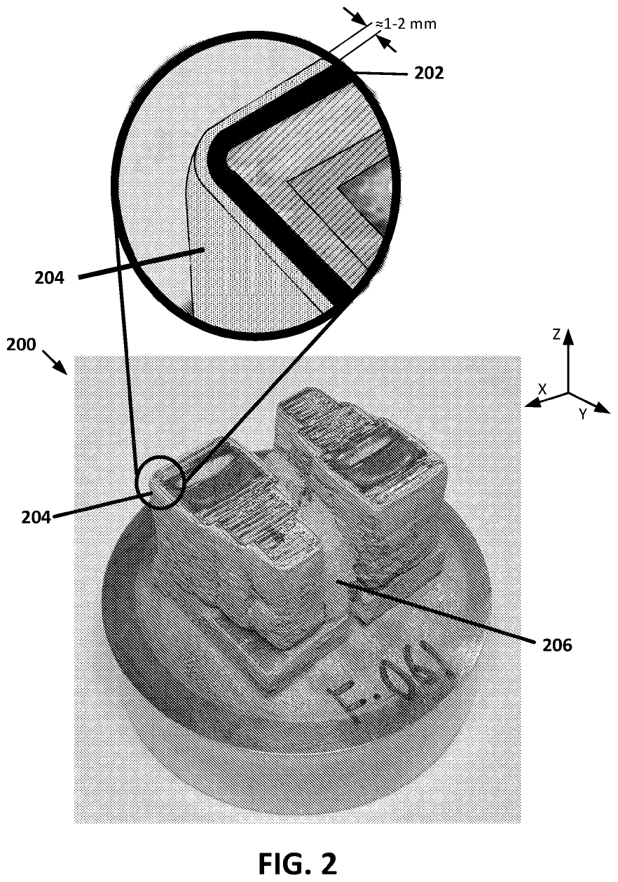

FIG. 2 is an illustration (e.g., a photograph) of a pair of 3D printed metal products 200 formed using an electron beam melting process according to some aspects of the disclosure. The 3D printed metal products 200 exhibit a polycrystalline shell 204 such as the polycrystalline shell 104 as shown and described in connection with FIG. 1. The edge grains (i.e., the polycrystalline shell 204) may be formed by nucleation on metal powder attached to the outer surface 202 (e.g., exterior surface) of each of the pair of 3D printed metal products 200. The polycrystalline shell 204 formed on the outer surface 202 of each of the pair of 3D printed metal products 200 may impinge (e.g., intrude, invade) into the final (net) surface of each of the pair of 3D printed metal products 200. An accumulation of unmelted metal powder 206 is depicted between the pair of 3D printed metal products 200. The thickness of the polycrystalline shell 204 in the example of FIG. 2 is about 1 mm, as shown.

During solidification, when a metal is molten and solidifies, the solidification begins on a surface that is cooler than the molten metal. A first atom of the molten metal may land on the cooler surface, cool down, solidify, and remain in place on the cooler surface. This atom and/or the surface to which it is attached may be referred to as a nucleation point. Other atoms may attach to the nucleation point, cool down, solidify, and remain in place, thus building the solid portion of the metal from the original cooler surface into the remaining molten metal.

In greater detail, as known to persons having ordinary skill in the art, nucleation may be understood as an initial process that takes place in the formation of a crystal from a solution, a liquid, or a vapor, in which a small number of ions, atoms, or molecules become arranged in a pattern characteristic of a crystalline solid, forming a site upon which additional ions, atoms, or molecules are deposited as the crystal grows.

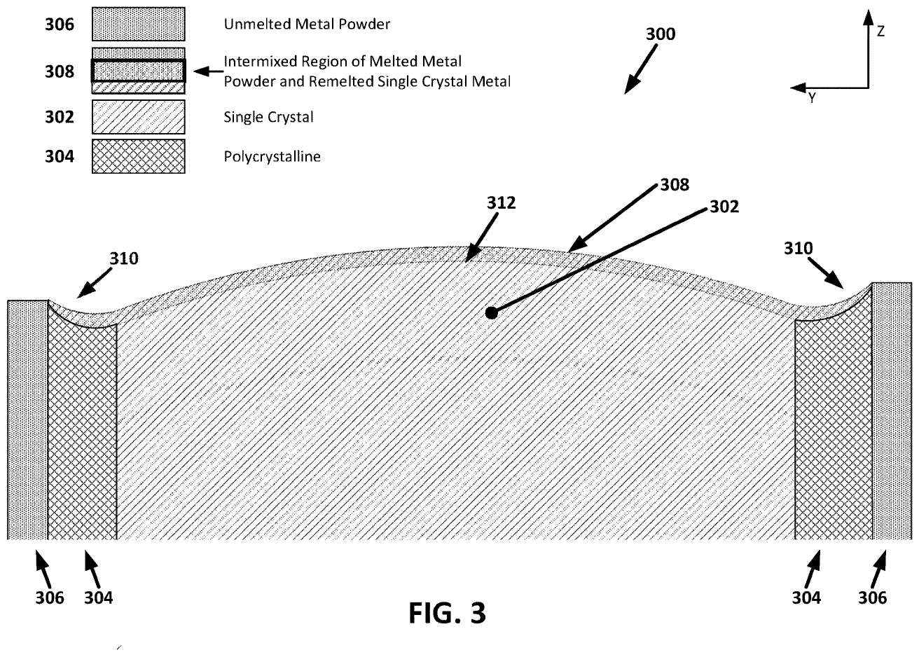

FIG. 3 is a simplified, not-to-scale, artist's rendition of a plurality of the uppermost layers (where the plurality of layers are not individually distinguished to avoid cluttering the drawing) of a cross-section of a second sample 300 of a metal product undergoing fabrication utilizing an electron beam melting metal additive manufacturing process according to some aspects of the disclosure. The second sample 300 may be similar to the first sample 100 as shown and described in connection with FIG. 1. The second sample 300 includes a single crystal 302 (e.g., a single crystal metal), a polycrystalline shell 304 (e.g., a polycrystalline metal shell), a bed of unmelted metal powder 306 in which the finished metal product is fabricated, and an intermixed region 308 (e.g., a melt pool) of melted metal powder and remelted single crystal 302 that is depicted atop uppermost layer(s) of the single crystal 302. It is noted that the width of the melt pool is exaggerated; in practice, the melt pool may be localized around the focal point of the electron beam on the surface of the metal product.

During the process of additive manufacturing, a layer of unmelted metal powder 306 is spread atop a heretofore processed layer of the metal part being fabricated. A portion of the unmelted metal powder 306 (corresponding to a cross-section of a slice of a desired metal part being fabricated) is completely melted along with a portion of the uppermost layer(s) of the single crystal 302. The melting of the unmelted metal powder 306 and the portion of the uppermost layer(s) of the single crystal 302 occur simultaneously so that both the melted metal powder and the remelted single crystal form the intermixed region 308 of melted metal powder and remelted single crystal metal.

The entire thickness (in the Z-axis direction) and width (in the X-Y plane) are allowed to solidify, thus building one layer atop a next layer in the Z-axis direction. It will be understood that each time an unmelted metal powder 306 layer is added, and that unmelted metal powder 306 layer (corresponding to a cross-sectional slice of the finished metal product) is melted and intermixed with a remelted portion of the single crystal 302, the atoms in the intermixed region 308 solidify beginning on atoms (e.g., surface atoms) of what is already the solid single crystal 302. Because the atoms of the single crystal 302 are already aligned with each other, the atoms of the melted metal powder and remelted single crystal in the intermixed region 308 will align with the already aligned atoms of the single crystal 302 during the solidification process. The newly solidified atoms will have the same alignment as those of the already aligned atoms of the single crystal 302. In other words, in response to an intermixed region 308 of atoms that include newly melted metal powder and remelted single crystal 302, given that nucleation of the atoms in the intermixed region 308 begins on the surface of the already aligned atoms of the solidified single crystal 302, the newly solidified atoms will, by their nature, align with and maintain the alignment of the atoms already present in the solidified single crystal 302.

However, the part being fabricated is built on a powder bed table that is covered with unmelted metal powder 306 each time a new layer is added. With each new layer, atoms of melted metal in the intermixed region 308, adjacent to the side regions 310, contact the particles, or grains, of unmelted metal powder 306 (at the left and right edges in the side regions 310 of the second sample 300) and nucleate upon those particles, or grains. Thus, grains of metal begin to grow toward an already existing surface 312 of the single crystal 302, creating the polycrystalline shell 304. Meanwhile, atoms adjacent to the already existing surface of the single crystal 302 nucleate on that existing surface and begin to grow from that existing surface.

Examples of the fabrication of metal parts formed as a single crystal 302 metal using additive manufacturing with a 3D metal printer are described herein. The additive manufacturing process may be an electron beam melting process, a high-power laser process (e.g., L-PBF), or a similar process that melts metal powder or metal-bearing material at the metal part's edges (e.g., walls). In the examples, the polycrystalline shell 304 may be prevented, converted to a single crystal, or removed.

According to a first aspect, metal powder, which would remain as unmelted metal powder 306 subsequent to a printing of a given layer of a desired metal part, may be removed after spreading a layer of unmelted metal powder 306 and prior to the printing (e.g., the melting) of a shape in the unmelted metal powder 306 corresponding to a cross-section of a slice of a desired metal product. The removal of the unmelted metal powder 306 (from areas of the entire layer that will not be melted and are adjacent to areas that will be melted) before melting eliminates a possibility of the atoms of molten metal (in what will become an intermixed region 308 of melted metal powder and remelted single crystal 302) from using particles of the unmelted metal powder 306 as nucleation sites, thus preventing, before it is created, the formation of the polycrystalline shell 304.

According to a second aspect, in instances where a polycrystalline shell 304 is formed, the polycrystalline shell 304 may be mechanically removed, using one or more tools (as opposed to chemically removed by etching) from the desired surface of the single crystal 302. Mechanical removal may be accomplished using, for example, a cutting tool or an abrasive tool. The preceding list is exemplary and not limiting.

In practice, in an electron beam melting process, unmelted metal powder is spread in a layer, and then the layer of unmelted metal powder may be sintered. For example, the electron beam may be configured to scan the layer at a power level that is not sufficient to melt the metal powder but is sufficient to cause the particles of the metal powder to stick together. In other words, and as is known to persons having ordinary skill in the art, a process of sintering may cause the unmelted metal powder to coalesce into a solid or porous mass by heating without liquefaction. Sintering may be used In the electron beam melting process because electrons from the electron beam gun are emitted into the vacuum chamber holding the printing apparatus and metal powder. Particles of the unmelted metal powder may become negatively charged by the electrons. Sintering, which coalesces adjacent particles, may be utilized to prevent adjacent negatively charged particles from being repelled electrostatically from one another. In some examples, sintering may be avoided when positive charges are pumped into the vacuum chamber to counteract and neutralize the negative charges emitted by the electron gun.

Consequently, in an electron beam melting process where sintering is used, the unmelted (but coalesced) metal powder particles are attached to the part being printed. Therefore, the unmelted metal particles are present and available to act as (undesired) nucleation sites.

In contrast, in a laser powder bed fusion process, the metal powder is spread in a layer but not sintered. The metal powder does not coalesce prior to printing (e.g., melting). However, in the laser powder bed fusion process, loose unmelted metal powder particles adjacent to a melt pool, which would remain as unmelted metal powder 306 subsequent to a printing of a given layer, do not remain at their locations but are drawn into (or blown into) the melt pool. The melt pool includes intended melted metal powder, remelted single crystal metal, and unintended loose unmelted metal powder particles adjacent to the melt pool (drawn into or blown into the melt pool). Because the loose, unmelted metal powder particles adjacent to the melt pool are drawn into (or blown into) the melt pool, those particles are unavailable as nucleation sites to the atoms of molten metal in the melt pool (e.g., in the intermixed region 308).

At least one aspect may be found to generate or produce a “wind” that may draw (or blow) the unmelted metal powder particles adjacent to the melt pool into the melt pool. For example, the wind (which may also be referred to as a localized air current or a convection current) may be created by the convection of an inert gas (e.g., argon) enveloping the melt pool itself. By way of explanation, the melt pool is very hot, which locally heats the inert gas in the vicinity of the melt pool and causes the heated inert gas to rise rapidly (i.e., to circulate by convection, to convect). The heated inert gas rising rapidly (e.g., quickly) above the melt pool draws inert gas in from the sides of the melt pool. The drawn-in inert gas, the wind, draws (or blows) the loose, unmelted metal powder particles adjacent to the melt pool into the melt pool.

According to another aspect, a directed jet or stream of inert gas may be directed toward the melt pool to blow the loose, unmelted metal powder particles adjacent to the melt pool into the melt pool. The directed jet or stream of inert gas may be introduced with a flow rate that is high enough to move the loose, unmelted metal powder particles adjacent to the melt pool into the melt pool yet not so high as to cool (or appreciably cool) the melt pool itself. The inert gas may be introduced into (blown into) the work area by a tool referred to herein as a positive-pressure inert gas nozzle.

According to another aspect, a physical property associated with the melt pool, such as surface tension, may help to move the loose, unmelted metal powder particles adjacent to the melt pool into the melt pool. The preceding aspects are exemplary and non-limiting.

The inert gas may envelope the melt pool and displace oxygen, nitrogen, and atmospheric contaminants that may cause inconstancies in the finished product. According to some examples, the inert gas may be called a shielding gas. In some laser powder bed fusion machines, the inert gas may be close to atmospheric pressure (e.g., very slightly above atmospheric pressure). Some laser powder bed fusion machines include a gas flow pump that flows the inert gas over the surface of the powder bed at a flow rate of about 1-3 meters per second (m/s). This flow rate may be fast enough to remove soot that is generated by the melting process but not fast enough to blow (e.g., move) loose particles of metal powder in any direction. Other flow rates are within the scope of the disclosure.

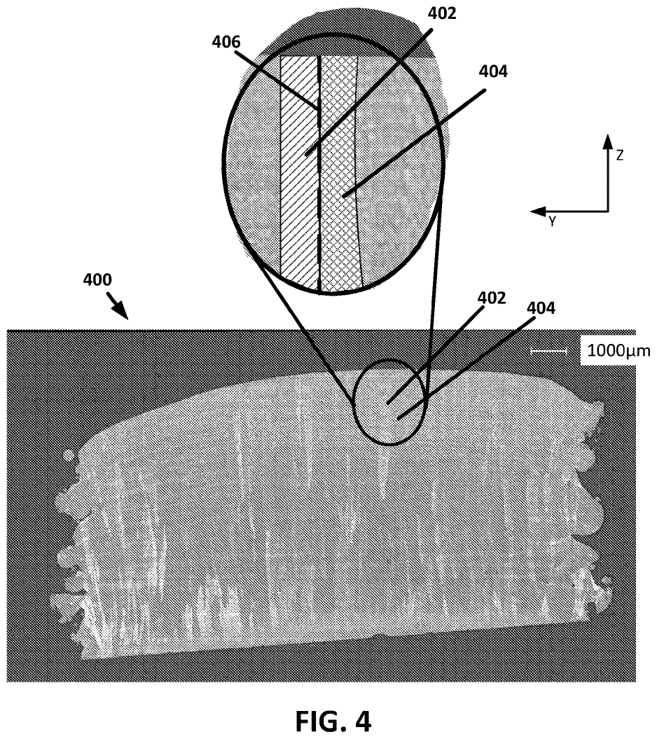

FIG. 4 is an illustration (e.g., a photograph) of a third sample 400 of a metal product fabricated using a laser powder bed fusion (L-PBF) metal additive manufacturing process according to some aspects of the disclosure. During the fabrication of the third sample 400, the inert gas enveloping the melt pool created a wind (e.g., by convection as explained above) that may have caused unmelted metal powder particles (that would have been left unmelted after the melting process because those particles were adjacent to an area defined by the shape of the cross-sectional slice being printed) to be drawn into (or blown into) the melt pool. Thus, those metal powder particles were not available as nucleation sites from which may have grown a polycrystalline shell, like the polycrystalline shell 104 and/or 204, as shown and described in connection with FIGS. 1 and/or 2, respectively.

Like the first sample 100, as shown and described in connection with FIG. 1, the third sample 400 was also prepared using a cross-sectional microscopy process, where the third sample 400 was cross-sectioned (from a larger piece), polished, and etched to reveal the grains within the third sample 400. Grains with different orientations respond differently to the etching fluid used to prepare the third sample 400.

By way of example, and for purposes of explanation only, a first grain 402, characterized as a vertical “spike” whose color (or shade) is different than a second grain 404 adjacent to the first grain 402, includes atoms of the metal that all have a first crystal orientation. The grain boundary 406 between the first grain 402 and the second grain 404 is depicted by a dashed line in the enlargement of a portion of the illustration of FIG. 4. The second grain 404 includes atoms of the same metal (as the first grain 402) that all have a second crystal orientation (where the second crystal orientation is different from the first crystal orientation). Observing the third sample 400, it is apparent (e.g., from the quantity of vertical spikes intermixed with more or less homogenized horizontal areas) that the metal of the third sample 400 is not an example of a single crystal.

However, the third sample 400 does provide an example in which the polycrystalline shell (such as the polycrystalline shell 104 and the polycrystalline shell 204, as shown and described in connection with FIGS. 1 and 2, respectively) is not present. In the third sample 400, the heat of the melt pool may have caused convection of the inert gas enveloping the melt pool to generate a “wind” (as explained above) that caused (undesired) unmelted metal particles adjacent to the melt pool to be drawn into (or blown into) the melt pool during a melting process, thus removing those unmelted metal particles adjacent to the melt pool as nucleation sites from which the polycrystalline shell may grow during a solidification process. As shown in the example of FIG. 4, there is no evidence of nucleation of new grains forming a polycrystalline shell. The example of FIG. 4, fabricated with the L-PBF process, only depicts grains growing outwardly toward and forming the edge of the third sample 400.

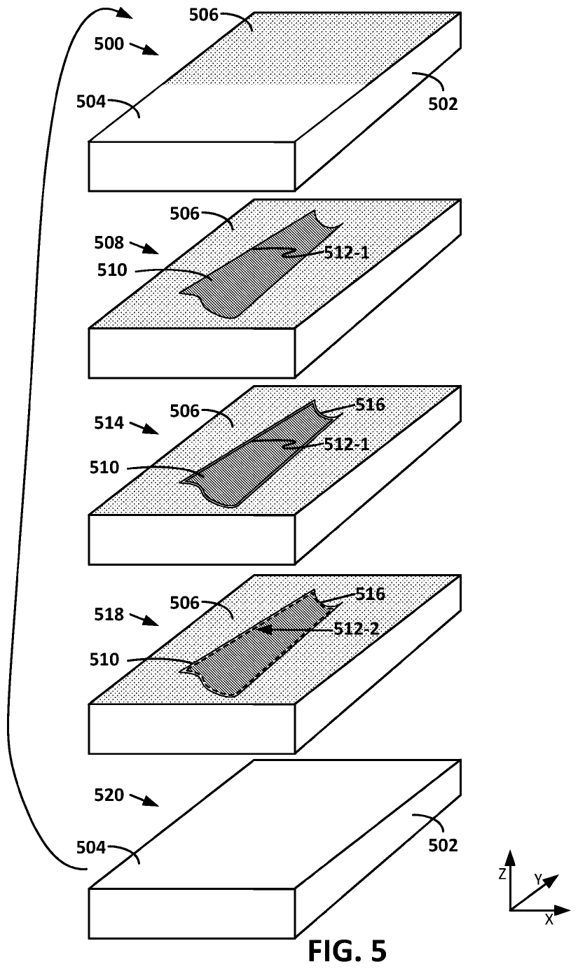

FIG. 5 is a pictographic example of a series of images that, taken together, may be used to explain the fabrication of a metal product (e.g., a metal part, a part) using a powder bed fusion metal additive manufacturing process according to some aspects of the disclosure. In the example of FIG. 5, the powder bed fusion process may be an electron beam melting process. However, the powder bed fusion process may be a laser powder bed fusion process, in which case, the sintering aspects may be omitted. For example, in one aspect, an apparatus performing the method of depicted in FIG. 5 may include an electron beam gun focused on the powder bed, and the apparatus may be configured to sinter the layer of unmelted metal powder prior to the melt, and perform the sinter, the melt, and the remelt using an electron beam emitted from the electron beam gun. In another aspect, an apparatus performing the method depicted in FIG. 5 may include a laser and the laser beam may be focused on the powder bed. In this aspect the apparatus may be configured to perform the melt, and the remelt with a laser powder bed fusion process.

The first pictograph 500 represents at least two processes. During the first process (which is already completed), a recoater head (not shown) traversed the powder bed 502 and deposited and leveled a first layer of unmelted metal powder 504 (e.g., SX superalloy metal powder) thereon. The term “first layer” as used in connection with FIG. 5 is a relative term. The depicted first layer of unmelted metal powder 504 may be a topmost layer of a plurality of already processed layers beneath (i.e., traversing the Z-axis toward the origin) the first layer. In the second process (which is in progress), an electron beam gun is sintering the first layer of unmelted metal powder 504 to transform the first layer of unmelted metal powder 504 into a sintered layer of unmelted metal powder (referred to herein as the sintered layer 506 herein for the sake of brevity).

The second pictograph 508 depicts a shape 510 corresponding to a cross-section of a layer (e.g., a slice) of the metal part after an electron beam melted the shape 510 into the sintered layer 506 (and into a portion of any single crystal metal immediately below the sintered layer 506). The shape 510 includes a single crystal metal and a polycrystalline metal.

The single crystal metal may be a first portion of a single crystal metal (or a first portion of the sintered layer 506), central to the shape 510 and approaching, from within the shape 510, a first melted edge 512-1. The first melted edge 512-1 may correspond to a projection of an outer wall of the shape 510 (e.g., a projection of a desired net outer surface of the outer wall of the shape 510, a final outer wall dimension of the shape 510) on the sintered layer 506. The first portion may have been nucleated upon a preexisting surface of the single crystal metal.

The polycrystalline metal may be a second portion of a polycrystalline metal (or a second portion of the sintered layer 506), proximal to the shape 510 and approaching, from outside the shape 510, the first melted edge 512-1. The second portion may have nucleated upon sintered unmelted metal powder rather than on the preexisting surface of the single crystal metal.

A zone that includes the first melted edge 512-1 surrounds the shape 510 and may include at least one of: the single crystal metal and the polycrystalline metal.

The third pictograph 514 depicts a tooled area 516 after a tool (not shown) removed sintered metal powder adjacent to the first melted edge 512-1. The tool may be, for example, a brush, a comb, a plurality of whiskers, a paddle or beam of any cross-section or combinations of cross-sections (e.g., circular, rectangular, oval, D-shaped, etc.) or the like, or a negative pressure vacuum nozzle, or a positive pressure inert gas nozzle. The preceding list was exemplary and non-limiting.

The fourth pictograph 518 depicts the shape 510 after the electron beam remelted the first melted edge 512-1. A remelted edge is identified as a remelted edge 512-2. The remelted edge 512-2 is depicted as a dashed black line to distinguish it from the solid black line used to depict the first melted edge 512-1 (e.g., in the second pictograph 508). The dashed line of the remelted edge 512-2 is not intended to indicate that the remelting has a stop-and-start, intermittent nature. The remelted edge 512-2 continuously and completely surrounds the shape 510 without any gaps. Furthermore, the dashed line of the remelted edge 512-2 is not intended to indicate that the edge or the shape 510 is optional.

Remelting the edge results in a melting of any polycrystalline shell that may have grown into the first melted edge 512-1. The remelting of the portion of the layer in the shape of the cross-section corresponds to remelting only the first melted edge 512-1 to form a second melted edge (i.e., the remelted edge 512-2). The second melted edge (i.e., the remelted edge 512-2) may be devoid of the polycrystalline metal. Remelting the metal of the polycrystalline shell in the absence of the sintered layer 506, removed from (e.g., brushed, displaced, blown, or vacuumed away from) the tooled area 516 facilitates the nucleation of atoms of the remelted metal on a surface of the single crystal. When solidified, those nucleated atoms adopt the orientation of the atoms of the single crystal and thus extend the single crystal to the edge (e.g., the net edge) of the part. Utilizing the processes described herein, the net shape of the part may be obtained in situ (e.g., situated in an original place, in place) without a need for post-process machining or etching.

The fifth pictograph 520 depicts the powder bed 502 after the recoater head (not shown) traversed the powder bed 502 and deposited and leveled a second layer of unmelted metal powder 504 atop the sintered layer 506 and the shape 510 (both covered and not shown in the fifth pictograph 520). According to some aspects, an amount of unmelted metal powder 504 layered atop the sintered layer 506 and the shape 510 should be sufficient to fill in the tooled area 516, which surrounds the shape 510.

As indicated by the arrow extending from the fifth pictograph 520 back to the first pictograph 500, the processes described and illustrated in FIG. 5 may be repeated until all layers of the part are printed.

In one example, FIG. 5 may depict a method of additively manufacturing a three-dimensional (3D) printed part. The method may include spreading a layer of unmelted metal powder 504 on the powder bed 502. The method may include melting a portion of the layer in a shape 510 of a cross-section of a corresponding layer of a plurality of layers of the additively manufactured 3D printed part. In this example, the method may include removing, utilizing a tool (not shown), metal powder adjacent to a first melted edge of the shape. For example, in a case in which a layer of unmelted metal powder 504 is sintered to form a sintered layer 506, the third pictograph 514 depicts a tooled area 516 after a tool (not shown) removed sintered metal powder adjacent to the first melted edge 512-1. The method may include remelting at least one of: the first melted edge, or the portion of the layer in the shape 510 of the cross-section of the corresponding layer of the plurality of layers of the additively manufactured 3D printed part. The method may still further include repeating the spreading, the melting, the removing, and the remelting at each successive layer of the plurality of layers of the additively manufactured 3D printed part.

In one example, the method may include sintering the layer of unmelted metal powder prior to the melting, and performing the sintering, the melting, and the remelting with an electron beam (e.g., an electron beam utilized in an electron beam melting process). In one example, the method may include performing the melting, and the remelting with a laser powder bed fusion process. In one example, the tool may be, but is not limited to, at least one of: a brush, a comb, a plurality of whiskers, a paddle, and a beam.

In one example, the method may further include spreading the layer of unmelted metal powder 504 on the powder bed 502 utilizing a recoater head (not shown) and positioning the tool (not shown) adjacent to the first melted edge 512-1 of the shape 510 utilizing a tool actuator (not shown) coupled to the recoater head.

In one example, the shape 510, prior to the remelting, may include a first portion of a single crystal metal, central to the shape and approaching the first melted edge from within the shape, the first portion having been nucleated upon a preexisting surface of the single crystal metal, and second portion of a polycrystalline metal, proximal to the shape and approaching the first melted edge from outside the shape, the second portion having been nucleated upon unmelted metal powder rather than on the preexisting surface of the single crystal metal. In the example, the first melted edge may correspond to a projection of an outer wall of the 3D printed part on the layer of the plurality of layers of the additively manufactured 3D printed part (or on the sintered layer 506). In the example, the first melted edge 512-1 may surround the shape 510 and may include at least one of: the single crystal metal and the polycrystalline metal.

In some examples, remelting the portion of the layer in the shape 510 of the cross-section corresponds to remelting only the first melted edge 512-1 to form a remelted edge 512-2 (e.g., a second melted edge). In such examples, the remelted edge 512-2 may be devoid of (e.g., lack) a polycrystalline metal.

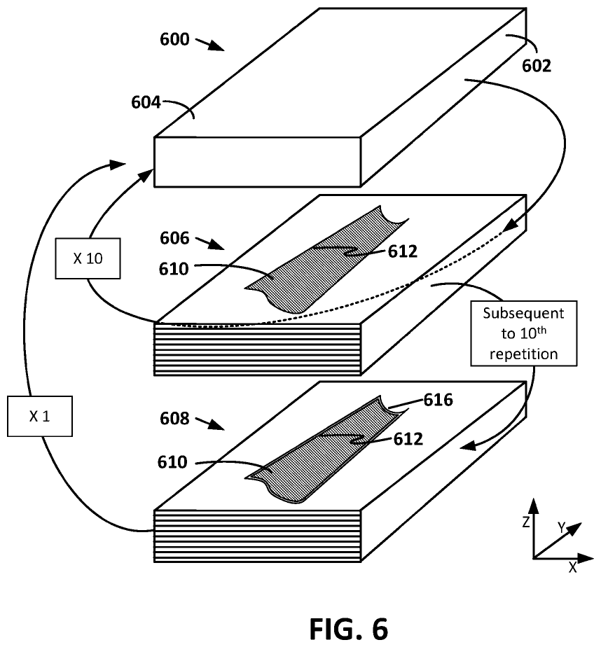

FIG. 6 is a pictographic example of a series of images that, taken together, may be used to explain the fabrication of a metal product (e.g., a metal part, a part) using a powder bed fusion metal additive manufacturing process according to some aspects of the disclosure. In the example of FIG. 6, the powder bed fusion process may be a laser powder bed fusion process or an electron beam melting process. With the electron beam melting process, each layer of unmelted metal powder would be sintered before printing (e.g., after (e.g., following, subsequent to) recoating and before (e.g., prior to) melting) a shape in the given layer. FIG. 6 does not depict the sintering process to avoid cluttering the drawing. Of course, the example of FIG. 6 is not limited to an electron beam melting process. In some aspects, the powder bed fusion process may be a laser powder bed fusion process, in which case, the sintering aspects may be omitted.

In other words, in one aspect, an apparatus performing the method of depicted in FIG. 6 may include an electron beam gun focused on the powder bed, and the apparatus may be configured to sinter the layer of unmelted metal powder prior to the melt, and perform the sinter, the melt, and the remelt using an electron beam emitted from the electron beam gun. In another aspect, an apparatus performing the method depicted in FIG. 6 may include a laser and the laser beam may be focused on the powder bed. In this aspect the apparatus may be configured to perform the melt, and the remelt with a laser powder bed fusion process.

The first pictograph 600 represents a powder bed 602 subsequent to a recoater head (not shown) traversing the powder bed 602 and depositing and leveling a first layer of unmelted metal powder (hereinafter “the first layer” 604) (e.g., SX superalloy metal powder) thereon. The term “first layer” as used in connection with FIG. 6 is a relative term. The first layer 604 may be a topmost layer of a plurality of already processed layers beneath (i.e., traversing the Z-axis toward the origin) the first layer.

The second pictograph 606 depicts a shape 610 corresponding to a cross-section of a layer (e.g., a slice) of the metal part after either a laser or an electron beam melted the shape 610 into the first layer 604 (and into a portion of any single crystal metal immediately below the first layer 604). Similar to the shape 510 as shown and described in connection with FIG. 5, the shape 610 includes a single crystal metal and polycrystalline metal. A zone that includes a melted edge (e.g., a first melted edge 612) surrounds the shape 610 and may include at least one of: the single crystal metal and the polycrystalline metal. In some examples, the shape 610 may be slightly oversized (e.g., a near-net shape) to facilitate the in situ (e.g., situated in an original place, in place) tooling described herein. The process depicted in the second pictograph 606 may be repeated a given number of times. For example, a total number of repetitions may be given as L, where L is an integer greater than 1. In the example of FIG. 6, the process may be repeated 10 times; a smaller number or a greater number than 10 is within the scope of the disclosure. The exemplary 10 repetitions of the process depicted in the second pictograph 606 are indicated by the box that includes the characters “X 10” and the arrow looping from the first pictograph 600 to the second pictograph 606, and back to the first pictograph 600.

The third pictograph 608 depicts a tooled area 616 after a tool (not shown) removed a polycrystalline shell (not shown) adjacent to the first melted edge 612 of the shape and to a depth corresponding to at least the given number of layers (e.g., 10 layers) corresponding to the given number of repetitions (e.g., 10 repetitions). The tool may be, for example, a cutting tool such as an end mill or a router bit, or an abrasive tool such as a burr, die grinder, or the like. The abrasive tool may be cylindrical or any other shape.

The process depicted by the third pictograph 608 may be implemented once every given number of repetitions. For example, in connection with FIG. 6, the process depicted by the third pictograph 608 may be implemented once every 10 repetitions. The implementation of once every 10 repetitions is indicated in the third pictograph 608 by the box reciting the words “subsequent to 10th repetition.” That box is associated with the arrow looping from the second pictograph 606 to the third pictograph 608. The box including the characters “X 1” is associated with the arrow looping from the third pictograph 608 up (back) to the first pictograph 600.

In one example, FIG. 6 may depict a method of additively manufacturing a three-dimensional (3D) printed part. The method may include spreading a layer of unmelted metal powder (e.g., the first layer 604 of unmelted metal powder as shown and described in connection with the first pictograph 600) on the powder bed 602.

The method may include melting a portion of the layer in a shape 610 of a cross-section of a corresponding layer of a plurality of layers of the additively manufactured 3D printed part, the portion of the layer having a melted edge (e.g., the first melted edge 612).

The method may include repeating the spreading and the melting of L−1 successive layers of metal powder corresponding to L−1 respective layers of the plurality of layers of the additively manufactured 3D printed part, where L is an integer greater than 1 and, removing, following the spreading and melting of a topmost layer (e.g., the Lth layer), utilizing a first tool (not shown), a polycrystalline shell (not shown) adjacent to the melted edge (e.g., the first melted edge 612) of each respective layer's melted edge of the shape to a depth of L layers relative to the topmost layer.

In one example, the method may include sintering the layer of unmelted metal powder prior to the melting; and performing the sintering, the melting the portion of the layer, the melting of L−1 successive layers, and the melting of the topmost layer with an electron beam melting process. In one example the method may include performing the melting the portion of the layer, the melting of L−1 successive layers, and the melting of the topmost layer with a laser powder bed fusion process.

In one example, in response to determining that additional layers corresponding to the plurality of layers of the additively manufactured 3D printed part are to be printed, the method may include repeating until all layers corresponding to the plurality of layers of the additively manufactured 3D printed part are printed: the spreading and melting of a next L successive layers of metal powder corresponding to a next L respective layers of the plurality of layers of the additively manufactured 3D printed part, followed by the removing, utilizing the first tool, the polycrystalline shell adjacent to each respective layer's melted edge of the shape to a depth of L layers relative to a next topmost layer.

In one example, the method may include performing the melting of the portion of the layer, the melting of L−1 successive layers, and the melting of the topmost layer with (e.g., using, utilizing) a laser powder bed fusion process.

In another example, the method may include performing the melting of the portion of the layer, the melting of L−1 successive layers, and the melting of the topmost layer with (e.g., using, utilizing) an electron beam melting process.

In an example that uses the electron beam melting process, for example, the method may include sintering each layer of unmelted metal powder following (e.g., after, subsequent to) spreading the each layer of unmelted metal powder on the powder bed.

In some examples, the first tool may be a cutting tool or an abrasive tool. Some examples of the cutting tool include an end mill or a router bit. Some examples of the abrasive tool include a burr or die grinder.

For example, the method may include removing, utilizing a second tool (not shown), unmelted metal powder adjacent to each respective layer's melted edge (e.g., the first melted edge 612) of the shape to a depth of L layers relative to a present layer. In some examples, the second tool may be but is not limited to, at least one of: a brush, a comb, a plurality of whiskers, a paddle, a beam, a negative pressure vacuum nozzle, and a positive pressure inert gas nozzle.

In some examples, the 3D printed part may be a single crystal 3D printed part devoid of polycrystalline metal, the polycrystalline shell removed in situ (e.g., situated in an original place, in place).

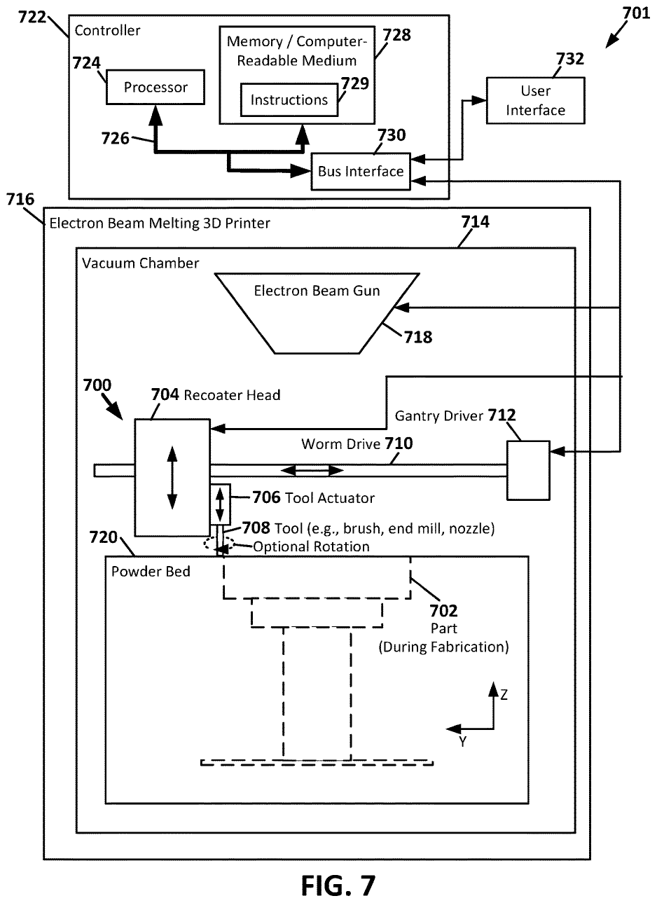

FIG. 7 is a block diagram of an example of a system 701 that may be used to remove unmelted metal powder from the edges of one or more additively manufactured printed layers of a 3D printed metal part (hereinafter “the part” 702) during fabrication (e.g., in situ) according to some aspects of the disclosure. The system 701 includes apparatus 700, which may be utilized with an electron beam melting process or a laser powder bed fusion process. The apparatus 700 may include a recoater head 704, a tool actuator 706 slidingly coupled to the recoater head 704, and a tool 708 fixedly, or optionally rotatably, that may be coupled to the tool actuator 706.

In the example of FIG. 7, the apparatus 700 is located in a vacuum chamber 714 in an electron beam melting 3D printer 716 and is thus configured for an electron beam melting process. The same apparatus 700 may be used in a laser powder bed fusion process, in which case the vacuum chamber 714 and the electron beam melting 3D printer 716 would be removed from FIG. 7, and a laser (not shown) would be substituted for the electron beam gun 718. Otherwise, the apparatus 700 (including the recoater head 704, the tool actuator 706, and the tool 708) as well as a gantry driver 712, a worm drive 710, a powder bed 720, a part 702, and a gantry (not shown) (may be configured to effectuate certain motion of the recoater head 704) may be used in either an electron beam melting process or a laser powder bed fusion process. The coupling of the tool and/or tool actuator to the gantry is for exemplary and non-limiting purposes and other apparatus, devices, etc. that may enable any tool, device, mechanism, or the like to interact with the part, such as but not limited to an independent gantry, mechanical arm, multiple axis articulated structures or the like, are within the scope of the disclosure.

The recoater head 704 may include one or more servo(s), motor(s), linear stepper motor(s), or the like, or a combination thereof (not shown) to effectuate vertical (up-down) motion (i.e., translation along the Z-axis). The tool actuator 706 may include one or more servo(s), motor(s), linear stepper motor(s), or the like, or a combination thereof (not shown) to effectuate vertical (up-down) motion (i.e., translation along the Z-axis) and to optionally effectuate rotational motion of the tool 708 (i.e., rotation about the Z-axis).

In some examples, where the tool 708 is configured to move, by displacement, unmelted metal powder (e.g., sintered or un-sintered metal powder that lies adjacent to an outer edge of a border of the part 702), the tool 708 may be, for example, a brush, a comb, a plurality of whiskers, a paddle or beam of any cross-section or combinations of cross-sections (e.g., circular, rectangular, oval, D-shaped, etc.) or the like. In some examples, where the tool 708 is configured to move, by displacement, unmelted metal powder (e.g., sintered or un-sintered metal powder that lies adjacent to an outer edge of a border of the part 702), the tool 708 may be, for example, a positive pressure inert gas nozzle or the like, that delivers, to a surface of the unmelted metal powder, a gas that blows the unmelted metal powder away from an outer edge of a border of the part 702 or into a melt pool during fabrication. In instances where the tool 708 is configured to remove, by cutting or abrasion, polycrystalline metal (e.g., melted metal powder that nucleated on a surface other than a desired single crystal surface), the tool 708 may be, for example, a cutting tool such as an end mill, a router bit, an abrasive cylinder, or the like. At least for tools in the nature of an end mill, a router bit, an abrasive cylinder, or the like, and as illustrated in FIG. 7, the tool actuator 706 may optionally be configured to rotate the tool 708.

The tool actuator 706 may be configured to rotate the tool 708 at a given or variable speed and in either direction. FIG. 7 only illustrates the clockwise direction to avoid cluttering the drawing. In instances where the tool 708 is configured to remove, by vacuum action, unmelted metal powder, sintered metal powder, and/or milled, routed, or abraded particles of polycrystalline metal and/or sintered metal powder (e.g., during or after in situ machining), the tool 708 may be, for example, a negative pressure vacuum nozzle coupled to a vacuum, a vacuum pump, or some other negative air pressure device. The preceding lists are exemplary and non-limiting. Although not shown to avoid cluttering the drawing, the tool 708 may be any combination of the preceding types of tools, and the tool actuator 706 may be configured to carry more than one of the tool 708 or any combination of more than one tool. For example, the tool 708 may be a spaced apart, adjacent, or coaxial combination of a cutting tool and a vacuum nozzle or a cutting tool and a brush, or a combination of a cutting tool, a brush, and a vacuum nozzle. The preceding combinations are illustrative and non-limiting. Any combination of two or more types of tools is within the scope of the disclosure.

According to some aspects, the recoater head 704 may be coupled to a worm drive 710. The worm drive 710 may be rotatably coupled to a gantry driver 712. The gantry driver may include one or more servo(s), motor(s), linear stepper motor(s), or the like (not shown). The gantry driver 712 may be configured to rotate the worm drive 710 (at separate times) clockwise and counterclockwise about a longitudinal axis of the worm drive 710 (e.g., about a Y-axis) to effectuate left-right motion of the recoater head 704 (i.e., translation along the Y-axis). The gantry driver 712 may be coupled to a gantry (not shown) and may be configured to effectuate forward-backward motion of the recoater head 704 (i.e., translation along the X-axis (where the X-axis is perpendicular to the plane of the figure)) by moving the gantry in the forward-backward directions. Worm gears and/or tracks that enable the forward-backward motion of the gantry and the gantry are omitted from FIG. 7 to avoid cluttering the drawing.

FIG. 7 depicts the apparatus 700 within a vacuum chamber 714 within an electron beam melting (EBM) 3D printer 716. An electron beam gun 718 is depicted above a powder bed 720. However, the apparatus 700 is not limited to placement within a vacuum chamber 714 or placement within a vacuum chamber 714 of an EBM 3D printer 716. For example, the apparatus 700 may be utilized with a laser (which would replace the electron beam gun 718) outside of the vacuum chamber 714 in connection with a laser powder bed fusion (L-PBF) 3D printer (not shown).

FIG. 7 also depicts a controller 722 employing one or more processors (generally represented by processor 724) that may be coupled to one or more memories (generally represented by memory/computer-readable medium 728) according to some aspects of the disclosure. Examples of processor 724 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the one or more processors (generally represented by processor 724), as utilized in the controller 722, may be configured to, individually or collectively, based at least in part on information stored in the one or more memories (generally represented by memory/computer-readable medium 728) implement (e.g., perform) any one or more of the functions, methods, processes, or aspects described and illustrated, for example, in FIGS. 1, 2, 3, 4, 5, and/or 6.

In this example, the controller 722 may be implemented with a bus architecture, represented generally by the bus 726. The bus 726 may include any number of interconnecting buses and bridges depending on the specific application of the controller 722 and the overall design constraints. The bus 726 communicatively couples together various circuits, including one or more processors (represented generally by the processor 724) and one or more memories (represented generally by a memory / computer-readable medium 728). The bus 726 may also link various other circuits such as timing sources, peripherals, voltage regulators, and power management circuits, which are well known to persons having ordinary skill in the art and, therefore, will not be described any further.

A bus interface 730 provides an interface between the bus 726, the gantry driver 712, the recoater head 704, and the tool actuator 706. The bus interface 730 may provide an interface between the bus 726 and a user interface 732 (e.g., keypad, display, touch screen, speaker, microphone, control features, vibration circuit/device, etc.). Of course, such a user interface 732 is optional and may be omitted in some examples.

One or more processors, represented individually and collectively by processor 724, may be responsible for managing the bus 726 and general processing, including the execution of software stored in/on the memory/computer-readable medium 728. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software (e.g., instructions), when executed by the processor 724, causes the controller 722 via the gantry driver 712, the recoater head 704, the tool actuator 706, and the tool 708 to perform the various processes and functions described herein for any particular apparatus.

The memory/computer-readable medium 728 may be a non-transitory computer-readable medium and may be referred to as a computer-readable storage medium or a non-transitory computer-readable medium. The non-transitory computer-readable medium may store computer-executable code (e.g., processor-executable code). The computer executable code may include code for causing a computer (e.g., a processor) to implement one or more of the various processes and functions described herein. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The memory/computer-readable medium 728 may reside in the controller 722, external to the controller 722, or be distributed across multiple entities, including the controller 722. The memory/computer-readable medium 728 may be embodied in a computer program product or article of manufacture. For example, a computer program product or article of manufacture may include a computer-readable medium in packaging materials. Persons having ordinary skill in the art will recognize how best to implement the described functionality presented throughout this disclosure depending on the particular application and the overall design constraints imposed on the overall system. The memory/computer-readable medium 728 may also be used to store data that is manipulated by the processor 724 when executing software (instructions 729).

According to one example, the controller 722 may be configured to perform an electron beam melting process (e.g., in the vacuum chamber 714 of the electron beam melting 3D printer 716, use the recoater head 704 to spread and level a layer of unmelted metal powder, sinter the layer of unmelted metal powder, melt a shape corresponding to a layer (e.g., a slice) of what will become the (finished) 3D printed part). At the end of each melting process, before recoating the just-processed layer with a new layer of unmelted metal powder, the controller may be configured to use a brush device on the recoater head 704 (e.g., where the brush may be a tool 708 coupled directly to the recoater head 707 or coupled indirectly via a tool actuator 706) to remove the sintered metal powder from around the top layers of the part. Subsequent to the removal of the sintered metal powder from around the top layers of the part, the controller may be configured to remelt the top layer (e.g., the part of the top layer that includes the printed slice) or remelt the edge around the top layers of the part, with no additional metal powder added, to remelt any polycrystalline shell that may have formed during the first melt and, by remelting the polycrystalline shell, create single crystal (to replace the polycrystalline shell). Once complete, the controller 722 may be configured to return to the process of recoating and leveling, sintering, and melting a next shape corresponding to a next layer of what will become the (finished) 3D printed part. It is noted that more metal powder than usual may be needed to “refill” the areas removed by the brushing.

In greater detail, the controller 722 may be configured to cause the recoater head 704 to spread a first layer of unmelted metal powder (e.g., SX superalloy metal powder) on the powder bed 720. The controller 722 may be further configured to cause the electron beam gun 718 to sinter the first layer of unmelted metal powder. The controller 722 may be further configured to cause the electron beam gun 718 to execute a first melt of a portion of the first layer of unmelted metal powder in a shape of a cross-section of one of a plurality of layers (e.g., slices) of an additively manufactured 3D printed metal part (e.g., the part 702). The first melt may form a single crystal volume (similar to the single crystal 102 and/or 302 as shown and described in connection with FIGS. 1 and/or 3, respectively) having a polycrystalline shell (similar to the polycrystalline shell 104, 204, and/or 304 as shown and described in connection with FIGS. 1, 2, and/or 3, respectively) adjacent thereto.

Subsequent to the first melt, the controller 722 may be further configured to cause the tool 708 to remove sintered metal powder adjacent to the outer edges of the melted metal powder (where, at this juncture, the outer edges of the melted metal powder may include at least some of the polycrystalline shell), each outer edge corresponding to a desired edge of the part 702. Subsequent to removal, the controller 722 may be further configured to cause the electron beam gun 718 to re-execute the first melt (in whole or around the outer edges of the melted metal powder). Re-executing the first melt results in a melting of any polycrystalline shell that may have grown adjacent to the outer edge corresponding to the desired edge of the part 702. Remelting the metal of the polycrystalline shell in the absence of the removed sintered metal powder facilitates the nucleation of atoms of the remelted metal on a surface of the single crystal volume. When solidified, those nucleated atoms will adopt the same orientation as the atoms of the single crystal. Subsequent to the remelting, the controller 722 may be further configured to cause the recoater head 704 to spread a second layer of unmelted metal powder on the powder bed 720.

According to one example, the controller 722 may be configured to perform either a laser powder bed fusion or an electron beam melting process. For example, using a laser powder bed fusion process, the controller may be configured to use the recoater head 704 to spread and level a layer of unmelted metal powder, and, using a laser (not shown), melt a shape corresponding to a layer (e.g., a slice) of what will become the (finished) part into the layer of unmelted metal powder. For example, using an electron beam melting process, the controller may be configured to, in a vacuum chamber 714 of an electron beam melting 3D printer 716, use the recoater head 704 to spread and level a layer of unmelted metal powder, sinter the layer of unmelted metal powder, melt a shape corresponding to a layer (e.g., a slice) of what will become the (finished) part. The laser powder bed fusion process or the electron beam melting process may be repeated for a given number of layers (e.g., 10 layers). Subsequently, the controller 722 may be configured to optionally use a vacuum cleaner or a brush to remove metal powder from around the melted regions, use a cutting tool to machine away the edge grains (e.g., the grains forming a polycrystalline shell around the single crystal portion of the melted regions), repeat the laser powder bed fusion process (e.g., repeated recoating and melting) or the electron beam melting process (e.g., repeated recoating, sintering, and melting) for another one of the given number of layers (e.g., another 10 layers), and continue until all layers of the part are complete.

In greater detail, the controller 722 may be configured to cause the recoater head 704 to spread a first layer of unmelted metal powder (e.g., SX superalloy metal powder) on the powder bed 720. The controller 722 may be further configured to cause the electron beam gun 718 to sinter the first layer of unmelted metal powder. The controller 722 may be further configured to cause a laser (not shown) or the electron beam gun 718 to execute a first melt of a portion of the first layer of unmelted metal powder in a shape of a cross-section of one of a plurality of layers (e.g., slices) of a finished additively manufactured 3D printed metal part (e.g., the part 702). The first melt may form a single crystal volume (similar to the single crystal 102 and/or 302 as shown and described in connection with FIGS. 1 and/or 3, respectively) having a polycrystalline shell (similar to the polycrystalline shell 104, 204, and/or 304 as shown and described in connection with FIGS. 1, 2, and/or 3, respectively) adjacent thereto. Subsequent to the first melt, the controller 722 may be further configured to repeat the process of recoating and melting a given number of times (for example, 10 times) and, subsequent to the given number of times, cause the tool 708 to remove a polycrystalline shell formed adjacent to the outer edge of the shape to a depth of at least the given number of layers (e.g., 10 layers). According to some aspects, the tool may be a cutting tool, such as an end mill or routing bit, or an abrasive tool, such as a burr or grinding bit.

Subsequent to removing the polycrystalline shell, the controller 722 may be further configured to repeat the given number of repetitions of recoating and melting (e.g., 10 repetitions), followed by the singular process of utilizing a cutting or abrasive tool to remove the polycrystalline shell to a depth of the given number of layers (e.g., 10 layers) over and over until all layers of the part have been printed.

The controller 722 may further be configured to execute the instructions 729 (e.g., software) stored in/on the memory/computer-readable medium 728 to implement one or more functions described herein.

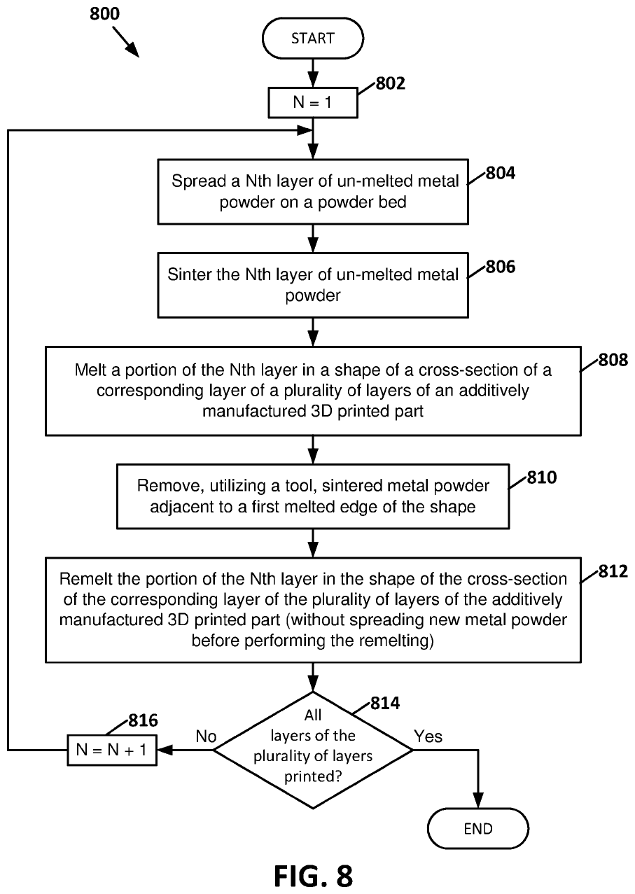

FIG. 8 is a flow chart illustrating an example process 800 (e.g., a method) of metal 3D printing utilizing additive manufacturing and an electron beam melting process in accordance with some aspects of the disclosure. As described below, some or all illustrated features may be omitted in a particular implementation within the scope of the present disclosure, and some illustrated features may not be required for implementation of all examples. In some examples, the process 800 may be carried out by the system 701, as shown and described in connection with FIG. 7. In some examples, the process 800 may be carried out by any suitable apparatus or means for carrying out the functions or algorithm described below.

At block 802, the system may set a value of a variable N equal to 1 (where N is an integer greater than or equal to 0). For example, the one or more processors (generally represented by processor 724 as shown and described in connection with FIG. 7), individually or collectively, may provide a means for setting a value of a variable N equal to 1.

At block 804, the system may spread an Nth layer of unmelted metal powder on a powder bed. For example, the recoater head 704 of the apparatus 700, as shown and described in connection with FIG. 7, may provide a means for spreading a Nth layer of unmelted metal powder on the powder bed. The powder bed 720 of the system 701 may be one example of the powder bed.

At block 806, the system may sinter the Nth layer of unmelted metal powder. For example, the electron beam gun 718 of the electron beam melting 3D printer 716, as shown and described in connection with FIG. 7, may provide a means for sintering the Nth layer of unmelted metal powder.

At block 808, the system may melt a portion of the Nth layer of unmelted metal powder in a shape of a cross-section of the Nth layer of a plurality of layers of a finished additively manufactured 3D printed part. For example, the electron beam gun 718 of the electron beam melting 3D printer 716, as shown and described in connection with FIG. 7, may provide a means for performing the first melt of a portion of the Nth layer of unmelted metal powder in a shape of a cross-section of the Nth layer of a plurality of layers of a finished additively manufactured 3D printed part.

At block 810, the system may remove, utilizing a tool, sintered metal powder adjacent to a first melted edges of the shape. For example, the tool 708 coupled to the recoater head 704 via the tool actuator 706, as shown and described in connection with FIG. 7, may provide a means for removing, utilizing a tool, sintered metal powder adjacent to a first melted edges of the shape. According to some aspects, the tool may be, for example, a brush, a comb, a plurality of whiskers, a paddle or beam of any cross-section or combinations of cross-sections (e.g., circular, rectangular, oval, D-shaped, etc.) or the like.

At block 812, the system may perform a second melt of the portion of the Nth layer in the shape of the cross-section of the Nth layer of the plurality of layers of the finished additively manufactured 3D printed part (without spreading new metal powder before performing the second melt). For example, the electron beam gun 718 of the electron beam melting 3D printer 716, as shown and described in connection with FIG. 7, may provide a means for performing a second melt of the portion of the Nth layer in the shape of the cross-section of the Nth layer of the plurality of layers of the finished additively manufactured 3D printed part (without spreading new metal powder before performing the second melt).

At block 814, the system may determine if all layers of the plurality of layers have been printed. For example, the one or more processors (generally represented by processor 724 as shown and described in connection with FIG. 7), individually or collectively, may provide a means for determining that all layers of the plurality of layers have not been printed. In response to determining that all layers of the plurality of layers have not been printed, the process 800 may continue to block 816.

At block 816, the system may increment the variable N by 1 (e.g., N=N+1). For example, the one or more processors (generally represented by processor 724 as shown and described in connection with FIG. 7), individually or collectively, may provide a means for incrementing the variable N by 1. Thereafter, the process 800 returns to block 804.

If, however, at block 814, in response to determining that all layers of the plurality of layers have been printed, the process 800 may end.

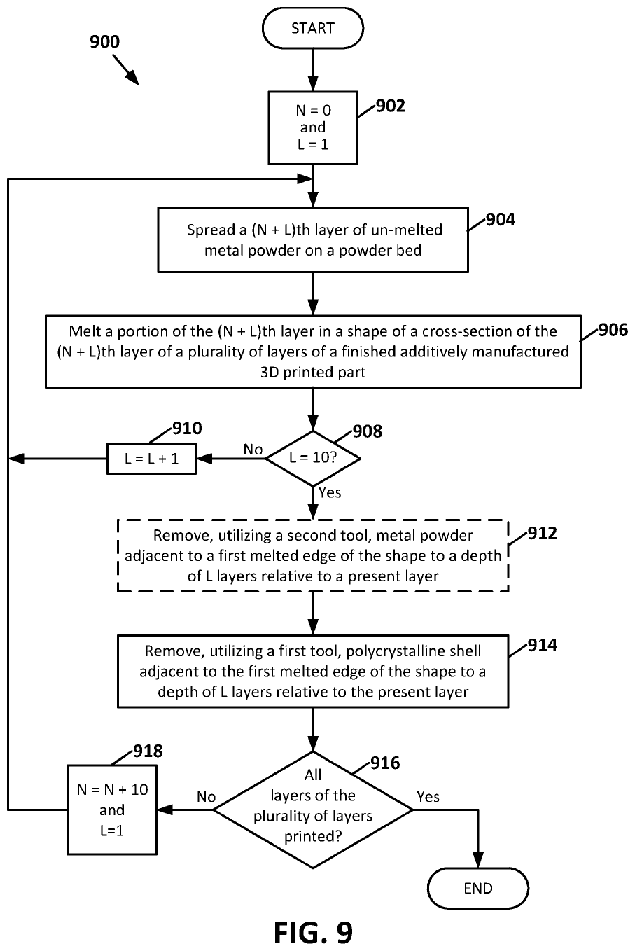

FIG. 9 is a flow chart illustrating an example process 900 (e.g., a method) of metal 3D printing utilizing an additive manufacturing process, such as a laser powder bed fusion process or an electron beam melting process, in accordance with some aspects of the disclosure. As described below, some or all illustrated features may be omitted in a particular implementation within the scope of the present disclosure, and some illustrated features may not be required for implementation of all examples. In some examples, the process 900 may be carried out by the system 701, as shown and described in connection with FIG. 7. In some examples, the process 900 may be carried out by any suitable apparatus or means for carrying out the functions or algorithm described below.

At block 902, the system may set a first value of a variable N equal to 0 (where N is an integer equal to or greater than 0) and a second value of a variable L equal to 1 (where L is an integer greater than 0). For example, the one or more processors (generally represented by processor 724 as shown and described in connection with FIG. 7), individually or collectively, may provide a means for setting a first value of a variable N equal to 0 and a second value of a variable L equal to 1.

At block 904, the system may spread a (N+L)th layer of unmelted metal powder on a powder bed. For example, the recoater head 704 of the apparatus 700, as shown and described in connection with FIG. 7, may provide a means for spreading a (N+L)th layer of unmelted metal powder on the powder bed. The powder bed 720 of the system 701 may be one example of the powder bed.

At block 906, the system may melt a portion of the (N+L)th layer of unmelted metal powder in a shape of a cross-section of the (N+L)th layer of a plurality of layers of a finished additively manufactured 3D printed part. For example, the electron beam gun 718 of the electron beam melting 3D printer 716, as shown and described in connection with FIG. 7 (or a laser (not shown) of a laser powder bed fusion system (not shown)), may provide a means for melting a portion of the (N+L)th layer of unmelted metal powder in a shape of a cross-section of the (N+L)th layer of a plurality of layers of a finished additively manufactured 3D printed part.

At block 908, the system may determine if the variable L is equal to a given number (e.g., L=10) (e.g., a predetermined given number). In the example of block 908, the given number (e.g., the predetermined given number) has a value of 10 for exemplary and non-limiting purposes. Other values of the given number are within the scope of the disclosure. For example, the one or more processors (generally represented by processor 724 as shown and described in connection with FIG. 7), individually or collectively, may provide a means for determining if the variable L is equal to a given number. In response to determining that L is not equal to a given number (e.g., L≠10), the process 800 may continue to block 910.

At block 910, the system may increment the variable L by 1 (e.g., L=L+1). For example, the one or more processors (generally represented by processor 724 as shown and described in connection with FIG. 7), individually or collectively, may provide a means for incrementing the variable L by 1. Thereafter, the process 800 returns to block 904.

If, however, at block 908, in response to determining that the variable L is equal to the given number (e.g., L=10), the process 800 may optionally continue to block 912, or if the option of block 912 is not taken, the process may continue to block 914.

At block 912, the system may optionally utilize a first tool to remove metal powder adjacent to the outer edges of the shape. For example, the tool 708 coupled to the recoater head 704 via the tool actuator 706, as shown and described in connection with FIG. 7, may provide a means for utilizing a first tool to remove metal powder adjacent to the outer edges of the shape. According to some aspects, the first tool may be, for example, a brush, a comb, a plurality of whiskers, a paddle or beam of any cross-section or combinations of cross-sections (e.g., circular, rectangular, oval, D-shaped, etc.) or the like.

At block 914, the system may utilize a second tool to remove polycrystalline shell adjacent to the outer edges of the shape. For example, the tool 708 coupled to the recoater head 704 via the tool actuator 706, as shown and described in connection with FIG. 7, may provide a means for utilizing a second tool to remove polycrystalline shell adjacent to the outer edges of the shape. According to some aspects, the second tool may be, for example, a cutting tool such as an end mill or a router bit, or an abrasive tool such as a burr, die grinder, or the like. The abrasive tool may be cylindrical or any other shape.

At block 916, the system may determine if all layers of the plurality of layers have been printed. For example, the one or more processors (generally represented by processor 724 as shown and described in connection with FIG. 7), individually or collectively, may provide a means for determining if all layers of the plurality of layers have not been printed. In response to determining that all layers of the plurality of layers have not been printed, the process 900 may continue to block 918.

At block 918, the system may increment the variable N by 10 (e.g., N=N+10), and the system may reset the variable L to equal 1 (e.g., L=1). In the example of block 918, the value of the variable N is given as 10, and the value of the variable L is given as 1 for exemplary and non-limiting purposes. Other values of N and L are within the scope of the disclosure. For example, the one or more processors (generally represented by processor 724 as shown and described in connection with FIG. 7), individually or collectively, may provide a means for incrementing the variable N by 10 and resetting the variable L to equal 1. Thereafter, the process 900 may return to block 904.

If, however, at block 916, in response to determining that all layers of the plurality of layers have been printed, the process 900 may end.

Of course, in the above examples, the circuitry included in the processor 724 of FIG. 7 is merely provided as an example. Other means for carrying out the described processes or functions may be included within various aspects of the present disclosure, including but not limited to the instructions 729 stored in/on the memory/computer-readable medium 728 of FIG. 7 or any other suitable apparatus or means described in any one of the FIGS. 5, 6, and/or 7 utilizing, for example, the processes and/or algorithms described herein in relation to FIGS. 1, 3, 4, 5, 6, 8, and/or 9.

Several aspects of 3D printing systems have been presented with reference to exemplary implementations. As persons having ordinary skill in the art will readily appreciate, various aspects described throughout this disclosure may be extended to other 3D printing systems.

According to one aspect, a system is described. The system may include one or more processors, one or more memories coupled to the one or more processors, a powder bed, an electron beam gun focused on the powder bed and coupled to the one or more processors, a recoater head coupled to the one or more processors, a tool actuator coupled to the recoater head and the one or more processors, and a tool coupled to the tool actuator. According to this aspect, the one or more processors may be configured to, individually or collectively, based at least in part on information stored in the one or more memories, spread, utilizing the recoater head, the layer of unmelted metal powder on the powder bed, sinter, utilizing an electron beam emitted by the electron beam gun, the layer of unmelted metal powder, melt, utilizing the electron beam emitted by the electron beam gun, a portion of the layer in a shape of a cross-section of a corresponding layer of a plurality of layers of an additively manufactured 3D printed part, remove, utilizing the tool, sintered metal powder adjacent to a first melted edge of the shape, remelt, utilizing the electron beam emitted by the electron beam gun, the portion of the layer in the shape of the cross-section of the corresponding layer of the plurality of layers of the additively manufactured 3D printed part, and repeat the spread, the sinter, the melt, the remove, and the remelt at each successive layer of the plurality of layers of the additively manufactured 3D printed part.

According to one aspect, a system is described. The system may include one or more processors, one or more memories coupled to the one or more processors, a powder bed, at least one of: a laser or an electron beam gun focused on the powder bed and coupled to the one or more processors, a recoater head coupled to the one or more processors, and a tool actuator coupled to the recoater head and the one or more processors, a tool coupled to the tool actuator. According to this aspect, the one or more processors may be configured to, individually or collectively, based at least in part on information stored in the one or more memories, spread a layer of unmelted metal powder on the powder bed, melt a portion of the layer in a shape of a cross-section of a corresponding layer of a plurality of layers of the additively manufactured 3D printed part, repeat the spreading and the melting of L−1 successive layers of metal powder corresponding to L−1 respective layers of the plurality of layers of an additively manufactured 3D printed part, where L is an integer greater than 1; and, following the spreading and melting of a topmost layer (e.g., the Lth layer), remove, utilizing a first tool, a polycrystalline shell adjacent to each respective layer's melted edge of the shape to a depth of L layers relative to the topmost layer.

According to one aspect, an apparatus is described. The apparatus may perform additive manufacturing of a three-dimensional (3D) printed part. The apparatus may include means for spreading a layer of unmelted metal powder on a powder bed, means for sintering the layer of unmelted metal powder, means for melting a portion of the layer in a shape of a cross-section of a corresponding layer of a plurality of layers of the additively manufactured 3D printed part, means for removing, utilizing a tool, sintered metal powder adjacent to a first melted edge of the shape, means for remelting the portion of the layer in the shape of the cross-section of the corresponding layer of the plurality of layers of the additively manufactured 3D printed part, and means for repeating the spreading, the sintering, the melting, the removing, and the remelting at each successive layer of the plurality of layers of the additively manufactured 3D printed part.

According to one aspect, an apparatus is described. The apparatus may perform additive manufacturing of a three-dimensional (3D) printed part. The apparatus may include means for spreading a layer of unmelted metal powder on a powder bed, means for melting a portion of the layer in a shape of a cross-section of a corresponding layer of a plurality of layers of the additively manufactured 3D printed part, means for repeating the spreading and the melting of L−1 successive layers of metal powder corresponding to L−1 respective layers of the plurality of layers of the additively manufactured 3D printed part, where L is an integer greater than 1; and, following the spreading and melting of a topmost layer, and means for removing, utilizing a first tool, polycrystalline shell adjacent to each respective layer's melted edge of the shape to a depth of L layers relative to the topmost layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features, and/or functions illustrated in FIGS. 1-9 may be rearranged and/or combined into a single component, step, feature, or function or embodied in several components, steps, or functions. Additional elements, components, steps, and/or functions may also be added without departing from novel features disclosed herein. The apparatus, devices, and/or components illustrated in FIGS. 1-9 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based on design preferences, it is understood that the specific order or hierarchy of steps in the methods may be rearranged. The method claims present elements of the various steps in a sample order and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language of the claims, wherein reference to an element in the singular is not intended to mean “one and only one” unless specifically so stated, but rather “one or more.” Unless specifically stated otherwise, the term “some” refers to one or more.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public, regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

As used herein, the term “determine” or “determining” encompasses a wide variety of actions and, therefore, “determining” can include calculating, computing, processing, deriving, investigating, looking up (such as via looking up in a table, a database, or another data structure), inferring, ascertaining, measuring, and the like. Also, “determining” can include receiving (such as receiving information), accessing (such as accessing data stored in memory), transmitting (such as transmitting information), and the like. Also, “determining” can include resolving, selecting, obtaining, choosing, establishing, and other similar actions.

As used herein, a phrase referring to “at least one of” a list of items refers to any combination of those items, including single members. For example, “at least one of: a, b, or c” is intended to cover: a, b, c, a-b, a-c, b-c, and a-b-c. As used herein, “or” is intended to be interpreted in the inclusive sense, unless otherwise explicitly indicated. For example, “a or b” may include a only, b only, or a combination of a and b. Similarly, a phrase referring to A and/or B may include A only, B only, or a combination of A and B.

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware, and software has been described generally in terms of functionality and illustrated in the various illustrative components, blocks, modules, circuits, and processes described above. Whether such functionality is implemented in hardware, firmware, or software depends upon the particular application and design constraints imposed on the overall system.

Various modifications to the examples described in this disclosure may be readily apparent to persons having ordinary skill in the art, and the generic principles defined herein may be applied to other examples without departing from the spirit or scope of this disclosure. Thus, the claims are not intended to be limited to the examples shown herein but are to be accorded the widest scope consistent with this disclosure, the principles, and the novel features disclosed herein.

Similarly, while operations are depicted in the drawings in a particular order, this should not be understood as requiring that such operations be performed in the particular order shown or in sequential order or that all illustrated operations be performed to achieve desirable results. Further, the drawings may schematically depict one or more example processes in the form of a flowchart or flow diagram. However, other operations that are not depicted can be incorporated into the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together into a single software product or packaged into multiple software products.

What is claimed is:

1. A method of additively manufacturing a three-dimensional (3D) printed part, comprising:
spreading a layer of unmelted metal powder on a powder bed;
melting a portion of the layer in a shape of a cross-section of a corresponding layer of a plurality of layers of the additively manufactured 3D printed part;
removing, utilizing a tool, metal powder adjacent to a first melted edge of the shape;
remelting at least one of: the first melted edge, or the portion of the layer in the shape of the cross-section of the corresponding layer of the plurality of layers of the additively manufactured 3D printed part; and
repeating the spreading, the melting, the removing, and the remelting at each successive layer of the plurality of layers of the additively manufactured 3D printed part.

2. The method of claim 1, further comprising:
sintering the layer of unmelted metal powder prior to the melting; and
performing the sintering, the melting, and the remelting with an electron beam.

3. The method of claim 1, further comprising:
performing the melting, and the remelting with a laser powder bed fusion process.

4. The method of claim 1, wherein the tool is at least one of: a brush, a comb, a plurality of whiskers, a paddle, and a beam.

5. The method of claim 1, further comprising:
spreading the layer of unmelted metal powder on the powder bed utilizing a recoater head; and
positioning the tool adjacent to the first melted edge of the shape utilizing a tool actuator coupled to the recoater head.

6. The method of claim 1, wherein the shape, prior to the remelting, includes:
a first portion of a single crystal metal, central to the shape and approaching the first melted edge from within the shape, the first portion having been nucleated upon a preexisting surface of the single crystal metal, and
a second portion of a polycrystalline metal, proximal to the shape and approaching the first melted edge from outside the shape, the second portion having been nucleated upon unmelted metal powder rather than on the preexisting surface of the single crystal metal,
wherein the first melted edge corresponds to a projection of an outer wall of the 3D printed part on the layer of the plurality of layers of the additively manufactured 3D printed part.

7. The method of claim 6, wherein the first melted edge surrounds the shape and includes at least one of: the single crystal metal and the polycrystalline metal.

8. The method of claim 1, wherein remelting the portion of the layer in the shape of the cross-section corresponds to remelting only the first melted edge to form a second melted edge.

9. The method of claim 8, wherein the second melted edge is devoid of a polycrystalline metal.

10. An apparatus, comprising:
a powder bed;
a recoater head configured to recoat the powder bed with unmelted metal powder;
a tool actuator coupled to the recoater head; and
a tool coupled to the tool actuator, wherein the apparatus is configured to:
spread, utilizing the recoater head, the layer of unmelted metal powder on the powder bed;
melt a portion of the layer in a shape of a cross-section of a corresponding layer of a plurality of layers of the additively manufactured 3D printed part;
remove, utilizing the tool, metal powder adjacent to a first melted edge of the shape;
remelt at least one of: the first melted edge, or the portion of the layer in the shape of the cross-section of the corresponding layer of the plurality of layers of the additively manufactured 3D printed part; and
repeat the spread, the melt, the remove, and the remelt at each successive layer of the plurality of layers of the additively manufactured 3D printed part.

11. A method of additively manufacturing a three-dimensional (3D) printed part, comprising:
spreading a layer of unmelted metal powder on a powder bed;
melting a portion of the layer in a shape of a cross-section of a corresponding layer of a plurality of layers of the additively manufactured 3D printed part, the portion of the layer having a melted edge;
repeating the spreading and the melting of L−1 successive layers of metal powder corresponding to L−1 respective layers of the plurality of layers of the additively manufactured 3D printed part, where L is an integer greater than 1; and
removing, following the spreading and melting of a topmost layer, utilizing a first tool, a polycrystalline shell adjacent to the melted edge of each respective layer to a depth of L layers relative to the topmost layer.

12. The method of claim 11, further comprising:
sintering the layer of unmelted metal powder prior to the melting; and
performing the sintering, the melting the portion of the layer, the melting of L−1 successive layers, and the melting of the topmost layer with an electron beam melting process.

13. The method of claim 11, further comprising:
performing the melting the portion of the layer, the melting of L−1 successive layers, and the melting of the topmost layer with a laser powder bed fusion process.

14. The method of claim 11 wherein, in response to determining that additional layers corresponding to the plurality of layers of the additively manufactured 3D printed part are to be printed, the method further comprises:
repeating, until all layers corresponding to the plurality of layers of the additively manufactured 3D printed part are printed:
the spreading and melting of a next L successive layers of metal powder corresponding to a next L respective layers of the plurality of layers of the additively manufactured 3D printed part, followed by
the removing, utilizing the first tool, the polycrystalline shell adjacent to each respective layer's melted edge of the shape to the depth of L layers relative to a next topmost layer.

15. The method of claim 10, wherein the first tool is a cutting tool or an abrasive tool.

16. The method of claim 15, wherein the cutting tool is an end mill or a router bit and the abrasive tool is a burr or die grinder.

17. The method of claim 11, further comprising:
removing, utilizing a second tool, unmelted metal powder adjacent to each respective layer's melted edge of the shape to a depth of L layers relative to a present layer.

18. The method of claim 17, wherein the second tool is at least one of: a brush, a comb, a plurality of whiskers, a paddle, a beam, a negative pressure vacuum nozzle, and a positive pressure inert gas nozzle.

19. The method of claim 11, wherein the 3D printed part is a single crystal 3D printed part devoid of polycrystalline metal, the polycrystalline shell removed in situ.

20. An apparatus, comprising:
a powder bed;
a recoater head configured to recoat the powder bed with an unmelted metal powder;
a tool actuator coupled to the recoater head; and
a tool coupled to the tool actuator, wherein the apparatus is configured to:
spread, utilizing the recoater head, a layer of the unmelted metal powder on the powder bed;
melt a portion of the layer in a shape of a cross-section of a corresponding layer of a plurality of layers of the additively manufactured 3D printed part, the portion of the layer having a melted edge;
repeat the spreading and the melting of L−1 successive layers of metal powder corresponding to L−1 respective layers of the plurality of layers of the additively manufactured 3D printed part, where L is an integer greater than 1; and
remove, following the spreading and the melting of a topmost layer, utilizing the tool, a polycrystalline shell adjacent to the melted edge of each respective layer to a depth of L layers relative to the topmost layer.
